(19) United States
(12) Patent Application Publication
(10) Pub. No.: US 2018/0040768 A1
(43) Pub. Date: Feb. 8, 2018

(54) SEMICONDUCTOR LIGHT EMITTING DEVICE AND METHOD OF MANUFACTURING THE SAME

(71) Applicant: SAMSUNG ELECTRONICS CO., LTD., Suwon-si (KR)

(72) Inventors: Shiyoung LEE, Seoul (KR); Sun Hyun OH, Yongin-si (KR); Sung Jun PARK, Busan-si (KR); Young Sub SHIN, Busan-si (KR); Kyoyoung AHN, Hwaseong-si (KR); Chi-yoon LEE, Hwaseong-si (KR)

(21) Appl. No.: 15/438,876

(22) Filed: Feb. 22, 2017

(30) Foreign Application Priority Data
Aug. 4, 2016 (KR) 10-2016-0099358

(51) Int. Cl. H01L 33/22; H01L 33/32; H01L 33/00; H01L 33/06

(52) U.S. Cl. CPC H01L 33/22; H01L 33/06; H01L 33/32; H01L 33/007

(57) ABSTRACT

A semiconductor light emitting device and a method of manufacturing a semiconductor light emitting device, the device including a substrate; a first conductive semiconductor layer on one surface of the substrate; an active layer on the first conductive semiconductor layer; a second conductive semiconductor layer on the active layer; and a plurality of protrusions on the second conductive semiconductor layer, the plurality of protrusions including an undoped semiconductor material, wherein an uneven complex surface structure including an unevenness that is a smaller size than a protrusion is formed in the second conductive semiconductor layer and is provided between the plurality of protrusions.

### CROSS-REFERENCE TO RELATED APPLICATION

Korean Patent Application No. 10-2016-0099358, filed on Aug. 4, 2016, in the Korean Intellectual Property Office, and entitled: “Semiconductor Light Emitting Device and Method of Manufacturing the Same,” is incorporated by reference herein in its entirety.

### BACKGROUND

### 1. Field

Embodiments relate to a semiconductor light emitting device and a method of manufacturing the same.

### 2. Description of the Related Art

A semiconductor light emitting device is a semiconductor device in which when current is applied, light of various phases can be generated by recoupling of electrons and holes at a junction portion of p and n type semiconductors. The semiconductor light emitting device may have various advantages including long life-span, low power, an excellent initial actuation characteristic, high vibration resistance, and the like as compared with a light emitting device based on a filament, and a demand for the semiconductor light emitting device continuously increases. For example, in recent years, a III-group nitride semiconductor which can emit blue based light of a short wavelength area has been spotlighted.

The above information disclosed in this Background section is only for enhancement of understanding of the background of the invention and therefore it may contain information that does not form the prior art that is already known in this country to a person of ordinary skill in the art.

### SUMMARY

The embodiments may be realized by providing a semiconductor light emitting device including a substrate; a first conductive semiconductor layer on one surface of the substrate; an active layer on the first conductive semiconductor layer; a second conductive semiconductor layer on the active layer; and a plurality of protrusions on the second conductive semiconductor layer, the plurality of protrusions including an undoped semiconductor material, wherein an uneven complex surface structure including an unevenness that is a smaller size than a protrusion is formed in the second conductive semiconductor layer and is provided between the plurality of protrusions.

The embodiments may be realized by providing a method of manufacturing a semiconductor light emitting device, the method including sequentially forming an undoped semiconductor layer, a second conductive semiconductor layer, an active layer, and a first conductive semiconductor layer on a semiconductor growth substrate; removing the semiconductor growth substrate; dry-etching the undoped semiconductor layer to form a plurality of protrusions from the undoped semiconductor layer and to partially expose the second conductive semiconductor layer; and forming an unevenness having a smaller size than the protrusions by supplying gas to the protrusions and the exposed second conductive semiconductor layer, the unevenness being on a surface of the protrusions and a surface of the exposed second conductive semiconductor layer.

The embodiments may be realized by providing a semiconductor light emitting device including a first conductive semiconductor layer; an active layer on the first conductive semiconductor layer; a second conductive semiconductor layer on the active layer; and a plurality of protrusions on the second conductive semiconductor layer, the plurality of protrusions including an undoped semiconductor material, the undoped semiconductor material being different from a material of the second conductive semiconductor layer, wherein a surface of the second conductive semiconductor layer between the protrusions has an uneven complex surface structure including an unevenness.

### BRIEF DESCRIPTION OF THE DRAWINGS

Features will be apparent to those of skill in the art by describing in detail exemplary embodiments with reference to the attached drawings in which:

FIG. 1 schematically illustrates a perspective view of a structure of a semiconductor light emitting device according to an exemplary embodiment.

FIG. 2 illustrates a cross-sectional view of the semiconductor light emitting device according to the exemplary embodiment of FIG. 1 taken along line II-II.

FIG. 3 separately illustrates one of a plurality of protrusions of FIGS. 1 and 2 in which an unevenness is positioned only on a part of the surface of the protrusion.

FIG. 4 separately illustrates one of the plurality of protrusions of FIGS. 1 and 2.

FIG. 5 schematically illustrates an array of a plurality of protrusions in a semiconductor light emitting device according to an exemplary embodiment.

FIG. 6 illustrates an image of a comparative example in which an unevenness is not formed on the surface of the protrusion and the surface of a semiconductor conductive semiconductor layer exposed between the protrusions.

FIG. 7 illustrates an image of an exemplary embodiment in which the unevenness is formed on the surface of the protrusion and the surface of the semiconductor conductive semiconductor layer exposed between the protrusions.

FIG. 8 illustrates front and cross-sectional images of the protrusion when a fill factor is close to 100% in the semiconductor light emitting device.

FIG. 9 illustrates a voltage application structure of a semiconductor light emitting device according to an exemplary embodiment.

FIG. 10 illustrates a voltage application structure of a semiconductor light emitting device according to another exemplary embodiment.

FIG. 11 illustrates a voltage application structure of a semiconductor light emitting device according to another exemplary embodiment.

FIG. 12 illustrates a voltage application structure of a semiconductor light emitting device according to yet another exemplary embodiment.

FIGS. 13 to 17 illustrate process diagrams schematically illustrating stages in a manufacturing process of a semiconductor light emitting device according to an exemplary embodiment.

FIG. 18 schematically illustrates a process of forming a conductive via in a semiconductor light emitting device.

### DETAILED DESCRIPTION

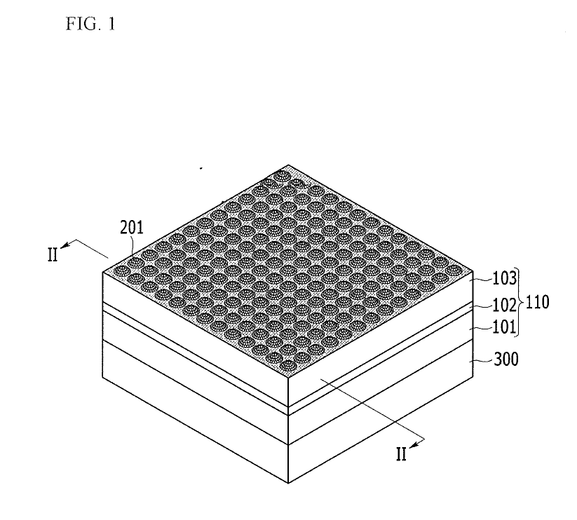

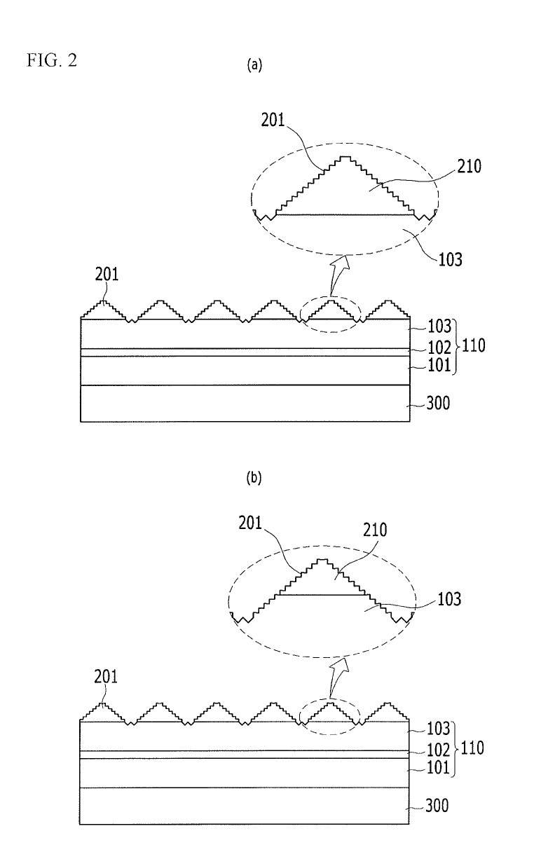

FIG. 1 schematically illustrates a structure of a semiconductor light emitting device according to an exemplary embodiment and FIG. 2 illustrates a cross-sectional view of the semiconductor light emitting device according to the exemplary embodiment of FIG. 1 taken along line II-II.

Referring to FIGS. 1 and 2, in the semiconductor light emitting device according to the exemplary embodiment, a light emitting structure 110 may be positioned on a substrate 300 and a plurality of protrusions 201 (including an undoped semiconductor material) may be positioned on the light emitting structure 110. The light emitting structure 110 may include, e.g., a first conductive semiconductor layer 101, an active layer 102, and a second conductive semiconductor layer 103.

An unevenness (having a smaller size than the protrusion 201) may be on a surface of the second conductive semiconductor layer 103 between the protrusions 201. For example, smaller peaks and valleys (e.g., sawtooth pattern) may be on the surface of the second conductive semiconductor layer 103 between the protrusions 201. In an implementation, the unevenness may be on a surface of the protrusion 201. For example, surfaces of the protrusions 201 may not be smooth, and may include small protrusions or peaks and valleys thereon.

In FIGS. 1 and 2, only several protrusions 201 positioned on the light emitting structure 110 are exemplarily illustrated for easy description and the number of protrusions 201 may be a suitable number of protrusions 201.

In the exemplary embodiment, the substrate 300 may include, e.g., Au, Ni, Al, Cu, W, Si, Se, or GaAs. Herein, the term “or” is not an exclusive term, and includes any combination of the described items. For example, the substrate may be non-conductive or conductive.

The first conductive semiconductor layer 101 may be a p-type semiconductor layer and the second conductive semiconductor layer 103 may be an n-type semiconductor layer. In an implementation, the first conductive semiconductor layer 101 and the second conductive semiconductor layer 103 may include a nitride semiconductor. The first conductive semiconductor layer 101 and the second conductive semiconductor layer 103 may have an AlₓIn_{y}Ga_{(1-x-y)}N composition equation (where, 0=x=1, 0=y=1, and 0=x+y=1). The first conductive semiconductor layer 101 and the second conductive semiconductor layer 103 may include GaN, AlGaN, or InGaN. In the present specification, materials including GaN in a chemical equation, e.g., GaN, AlGaN, and InGaN, are referred to as GaN or a GaN based material. In an implementation, the first conductive semiconductor layer 101 may include a p doped nitride semiconductor material and the second conductive semiconductor layer 103 may include an n doped nitride semiconductor material. As one example, the first conductive semiconductor layer 101 may include p doped GaN and the second conductive semiconductor layer 103 may include n doped GaN.

The active layer 102 may emit light having predetermined energy by recoupling or recombining of electrons and holes, and may have a multiple quantum well (MQW) structure in which a quantum well layer and a quantum barrier layer are laminated alternatively to alternately with each other. In the case of the multiple quantum well structure, the active layer 102 may have a InGaN/GaN structure.

The plurality of protrusions 201 may be positioned on the second conductive semiconductor layer 103, and the protrusions 201 may include an undoped semiconductor material 210.

Undoping means not performing an impurity doping process on the semiconductor layer. For example, the undoping includes a case where Si used as a dopant, and the like is included as an impurity concentration at a level to be originally present on the semiconductor layer, e.g., at a level of approximately 10¹⁴ to 10¹⁵/cm³ even though not intended when a GaN semiconductor is grown by using MOCVD. In an implementation, the undoped semiconductor material 201 may be intentionally undoped GaN. In an implementation, the undoped semiconductor material 201 may be an intrinsic semiconductor material.

In an implementation, as illustrated in part (a) of FIG. 2, the protrusion 201 may include only the undoped semiconductor material 210 therein. In an implementation, as illustrated in part (b) of FIG. 2, the protrusion 201 may have a two layer structure, e.g., may further include a material of the second conductive semiconductor layer 103 on or at a lower layer thereof.

During an etching process for forming the plurality of protrusions 201, this will depend on etching depths of the undoped semiconductor layer and the second conductive semiconductor layer. When the protrusion 201 is formed, the protrusion 201 may be formed by depositing and etching the undoped semiconductor layer. During such a process, the protrusion 201 may be etched to include only the undoped semiconductor material 210 or etched to include the undoped semiconductor material 210 and the part of the second conductive semiconductor layer (103) material inside or at the bottom of the protrusion 201.

The protrusions 201 may be regularly arranged on the second conductive semiconductor layer 103 to constitute an uneven structure and to help increase extraction efficiency of light emitted from the light emitting structure 110. In an implementation, the unevenness may be positioned on the surface of the second conductive semiconductor layer 103 between the protrusions 201. In an implementation, the unevenness may be the surface of the protrusion 201 to help increase the extraction efficiency of the light. For example, the unevenness on the surface of the protrusion 201 and between the protrusions 201 may help reduce total reflection of light generated on a flat interface of the semiconductor layer and air. For example, the semiconductor light emitting device according to the exemplary embodiment may have an uneven complex surface structure in which the unevenness having a smaller size than the protrusion 201 is further positioned on the surface between the plurality of protrusions 201 to help enhance the extraction efficiency of the light.

In an implementation, the unevenness on the surface of the protrusion 201 may be on the entire surface of the protrusion or only on a part of the surface of the protrusion. In an implementation, the unevenness on the surface of the protrusion 201 may cover an area of, e.g., 70 to 100% of the surface of the protrusion. In this case, the unevenness may be regularly positioned on the surface or irregularly positioned on the surface of the protrusion.

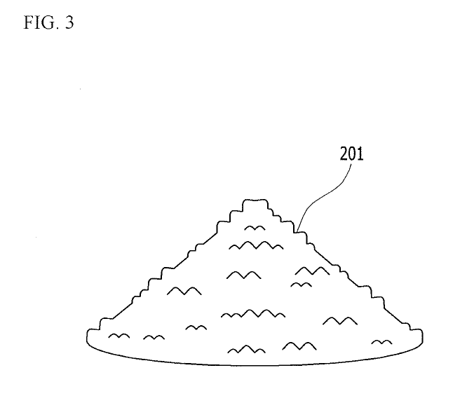

FIG. 3 illustrates an exemplary embodiment in which the unevenness is only on a part of the surface of the protrusion according to an exemplary embodiment. Referring to FIG. 3, the unevenness may only be on a part of the surface of the protrusion and the unevenness may not be positioned on another part of the surface of the protrusion.

In other drawings other than FIG. 3 of the present specification, it is illustrated as if the unevenness is on the entirety of the surface of the protrusion, but this is used for easy description and illustration.

In an implementation, sizes and an arrangement period of the protrusions 201 may be regular. In an implementation, the protrusion 201 may have a shape similar to a cone. In the present specification, the shape similar to the cone is a concept including all structures in which the bottom or base is circular or rounded and a diameter of a section is shortened or reduced in a direction upward from the base (e.g., away from the substrate). In an implementation, the shape may include a case where a generating line of the cone is a straight line and a case where the generating line is a curve having an arc.

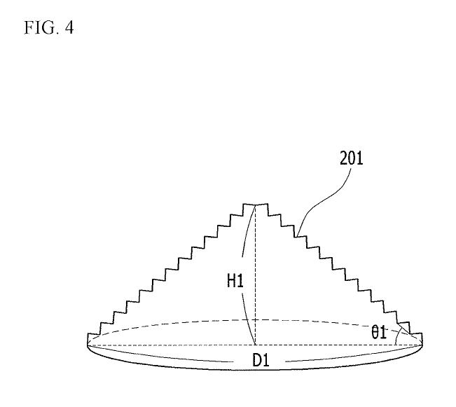

FIG. 4 separately illustrates one of a plurality of protrusions illustrated in FIGS. 1 and 2. Referring to FIG. 4, an angle θ1 formed by the side and the bottom of the protrusion 201 may be in the range of, e.g., 30° to 60° in the exemplary embodiment. Maintaining the angle formed by the side and the bottom of the protrusion 201 at 60° or less may help ensure that the generated light is not trapped between the protrusion 201 and the protrusion 201, thereby preventing a deterioration of light emitting efficiency. Maintaining the angle formed by the side and the bottom of the protrusion at 30° or greater helps ensure that enhancement of the light emitting efficiency by the formation of the protrusion is sufficient.

A height H1 of the protrusion 201 may be, e.g., between 1 to 2 μm. In an implementation, the bottom or base of each protrusion may be circular, and a diameter D1 of each protrusion may be, e.g., 2.7 to 3.2 μm.

The diameters of the bottoms of the protrusions 201 may coincide with each other in an entire area of the second conductive semiconductor layer 103 (e.g., may be uniform in all of the protrusions 201) or may be different from each other. In an implementation, the diameters of the bottoms of adjacent protrusions may be different from each other, and a difference of the diameters may be within, e.g., less than, 20%.

In an implementation, three protrusions in which the diameters of the bottoms are a first size, a second size, and a third size, respectively may be regularly positioned. For example, the three protrusions having the first, second, and third sizes may constitute one unit and the unit may be repeatedly positioned.

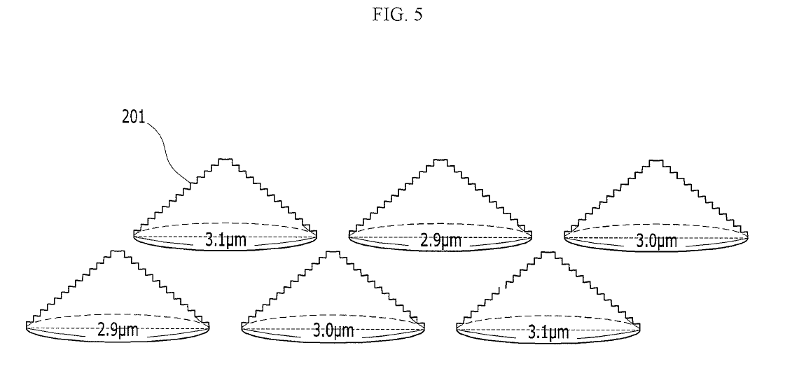

In an implementation, the first size may be in the range of 2.7 to 2.95 μm, the second size may be in the range of 2.95 to 3.05 μm, and the third size may be in the range of 3.05 to 3.2 μm. In an implementation, the first size may be 2.9 μm, the second size may be 3.0 and the third size may be 3.1 μm. FIG. 5 schematically illustrates an array of a plurality of protrusions in a semiconductor light emitting device according to an exemplary embodiment. Referring to FIG. 5, three protrusions 201 in which the diameters of the bottoms are 2.9 μM, 3.0 and 3.1 μm, respectively may be regularly alternately positioned.

In an implementation, the plurality of protrusions 201 having different sizes may be regularly positioned or the plurality of protrusions 201 having the same bottom diameter may be regularly positioned.

Referring back to FIGS. 1 and 2, in an implementation, the size of the unevenness formed on the surface of the second conductive semiconductor layer 103 may be larger than the size of the unevenness formed on the surface of the protrusion 201. For example, most of the protrusions 201 may include the undoped semiconductor material 210, the second conductive semiconductor layer 103 may include the doped semiconductor layer material, and the protrusion 201 and the second conductive semiconductor layer 103 have different physical properties. The surface of the protrusion 201 may be sloped or inclined, the surface between the protrusions 201 may be planar (e.g., parallel with the substrate), and a formation of the unevenness may vary due to a difference in structure in a process for forming the unevenness. In an implementation, a ratio of an average size of the unevenness (e.g., an average height of peaks from bottoms of the valleys) on the surface of the protrusion 201 and an average size of the unevenness between the protrusions 201 may be, e.g., 1:1 to 1:3. For example, the average size of the unevenness between the protrusions 201 may be larger than the average size of the unevenness on the surface of the protrusion 201 by approximately 30%.

For example, when the unevenness is formed on the surface of the protrusion 201 and the surface of the second conductive semiconductor layer 103 exposed between the protrusions 201, the unevenness on the surface may help enhance the light extraction efficiency, and as a result, an effect as if a fill factor of the protrusion is 100% may be shown or achieved.

In order to maximize the light extraction efficiency of the light emitting structure, the fill factor of the protrusion formed in the light emitting structure may be close to 100%. The fill factor is a ratio representing a fill degree of particles or protrusions to a predetermined space. In an implementation, when the protrusion is positioned on the surface of the light emitting structure without an empty space (e.g., between the protrusions), the fill factor becomes 100%. Accordingly, in the semiconductor light emitting device having the uneven complex structure according to the exemplary embodiment, even though the fill factor of the protrusions may not be 100%, the light extraction efficiency may be enhanced similarly to the case where the fill factor is substantially 100% due to a (e.g., small) unevenness positioned between the protrusions.

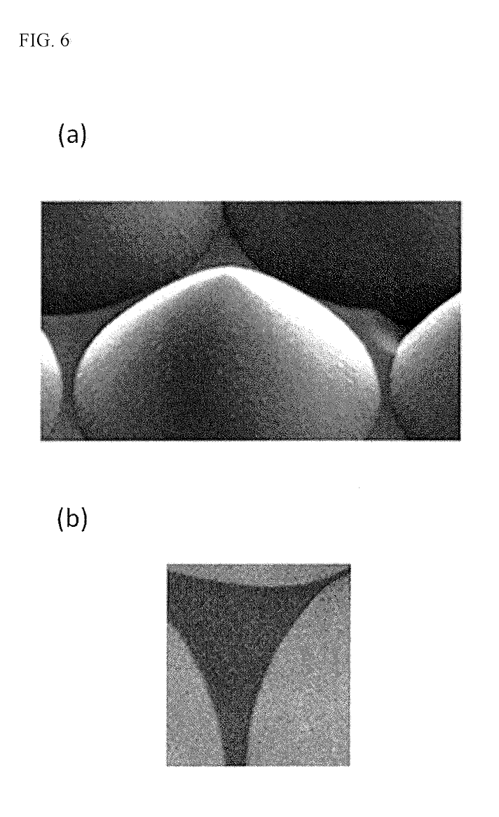

An effect of the semiconductor light emitting device according to the exemplary embodiment will be described in more detail with reference to FIGS. 6 to 8.

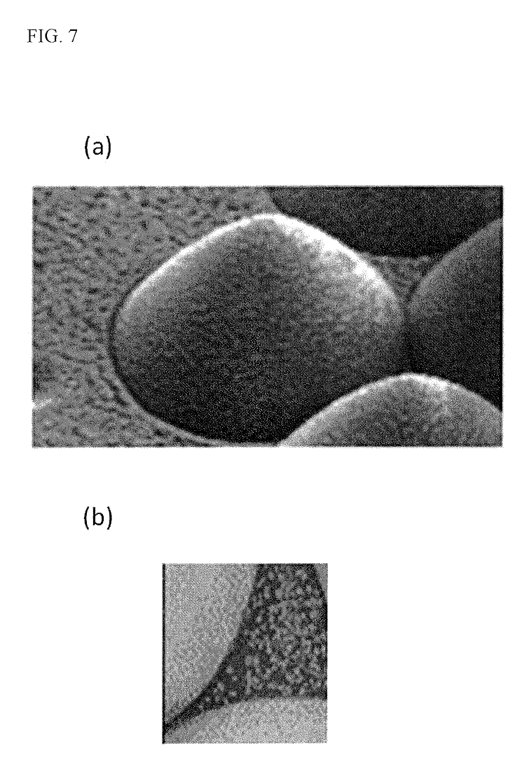

FIG. 6 illustrates an image of a comparative example in which unevenness is not formed on a surface of the protrusion and not formed on the surface of a semiconductor conductive semiconductor layer exposed between the protrusions. FIG. 7 illustrates an image of an exemplary embodiment in which the unevenness is formed on the surface of the protrusion and on the surface of the semiconductor conductive semiconductor layer exposed between the protrusions. Part (b) of FIG. 6 and part (b) of FIG. 7 illustrate images in which part (a) of FIG. 6 and part (a) of FIG. 7, respectively, are enlarged.

Referring to FIG. 7, a plurality of protrusions may be formed in the semiconductor light emitting device according to the exemplary embodiment, and the unevenness may be formed on the surface of the protrusion and even on the surface of the second conductive semiconductor layer exposed between the protrusions. As a result, the entire surface may have roughness. Therefore, the semiconductor light emitting device may have the light extraction efficiency similar to the case where the fill factor is substantially 100%, even though the fill factor of the protrusions may not be 100%.

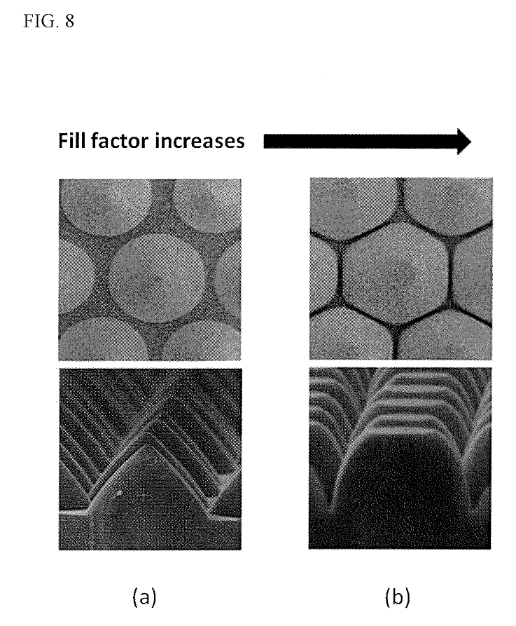

FIG. 8 illustrates front and cross-sectional images of the protrusion when a fill factor is close to or approaches 100% (A->B) in the semiconductor light emitting device. Referring to part (a) of FIG. 8, when the bottom of the protrusion is circular, a blank or open area may be present between adjacent circles, and the fill factor may not be 100%. In one case, the bottom of the protrusion may be hexagonal so that the fill factor becomes or approaches 100%, as illustrated in part (b) of FIG. 8.

In this case, the protrusion may have a hexagonal column shape. In a hexagonal column structure, an angle formed by the side and the bottom of the protrusion may be more than 60°. As shown in part (b) of FIG. 8, the angle formed by the side and the bottom of the protrusion may be close to a right angle (90°). If the angle formed by the side and the bottom of the protrusion were to be more than 60°, the extracted light could be trapped between the protrusions, and as a result, the light extraction efficiency could deteriorate.

However, referring to FIG. 7, the semiconductor light emitting device according to the exemplary embodiment may have the uneven complex surface structure (in which the unevenness having a smaller size than the protrusion is formed on the surface between the protrusions), the light extraction efficiency similar to the case in which the fill factor of 100% may be shown without a situation in which the light is trapped between the protrusions. Accordingly, the efficiency of the semiconductor light emitting device may be enhanced.

Luminance for each of the semiconductor light emitting device having the surface structure of FIG. 6 and the semiconductor light emitting device having the surface structure of FIG. 7 may be measured. In this case, the semiconductor light emitting devices used for the measurement as the semiconductor light emitting device having the structure illustrated in FIG. 1 have only different surface structures and thereafter, the luminance of each of the semiconductor light emitting devices may be measured as illustrated in FIGS. 6 and 7. In this case, the first conductive semiconductor layer 101 may include p doped GaN and the second conductive semiconductor layer 103 may include n doped GaN, and the protrusion 201 may include GaN which is not doped. As a result, it may be seen that the luminance of the semiconductor light emitting device having the surface structure of FIG. 7 may be higher than the luminance of the semiconductor light emitting device having the surface structure of FIG. 6 by 1.4%.

Further, the respective semiconductor light emitting devices having the surface structures of FIGS. 6 and 7 may be packed and thereafter, the luminance of each semiconductor light emitting device may be measured. In the measurement, the semiconductor light emitting device may be bonded to a package substrate and a fluorescent body may be laid, a lens may be covered and thereafter, the luminance may be measured. As a result, it may be seen that the luminance measured by packaging the semiconductor light emitting device having the surface structure of FIG. 7 may be higher than the luminance measured by packaging the semiconductor light emitting device having the surface structure of FIG. 6 by 0.5%.

As described above, the semiconductor light emitting device according to the exemplary embodiment, which has the uneven complex structure, may have an effect similar to a case in which the fill factor is substantially 100%, e.g., due to the small unevenness positioned on the surface between the protrusions. The light extraction efficiency and the light emitting efficiency of the semiconductor light emitting device may be enhanced.

Hereinabove, the semiconductor light emitting device has been briefly described based on a lamination form and a lamination structure and hereinafter, a voltage application structure of the semiconductor light emitting device will also be described in more detail.

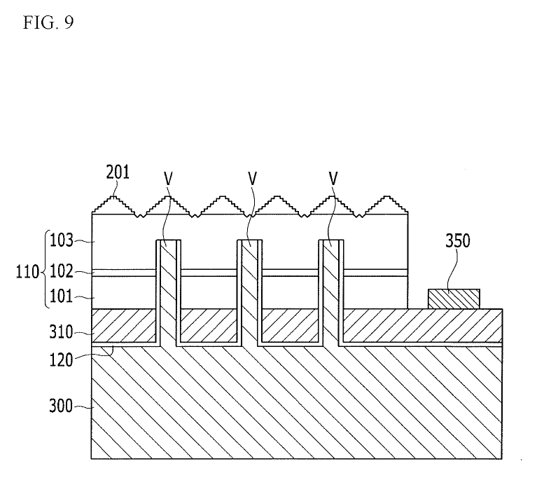

FIG. 9 illustrates a voltage application structure of a semiconductor light emitting device according to an exemplary embodiment. Referring to FIG. 9, in the semiconductor light emitting device according to the exemplary embodiment, a light emitting structure 110 including a first conductive contact layer 310 and a first conductive semiconductor layer 101, the active layer 102, and a second conductive semiconductor layer 103 may be positioned on a substrate 300 and a plurality of protrusions 201 may be positioned on the second conductive semiconductor layer 103. An unevenness having a smaller size than the protrusion 201 may be present on the surface of the second conductive semiconductor layer 103 between the protrusions 201. In an implementation, the unevenness having the smaller size than the protrusion 201 may also be on the surface of the protrusion 201. Description of the unevenness on the surfaces of the projection 201 and the second conductive semiconductor layer 103 according to the exemplary embodiment may be the same as the above description and detailed description of the same component may be omitted.

The light emitting structure 110 may not be positioned on a part of the first conductive contact layer 310, which may be exposed to the outside and a first electrode pad 350 may be positioned at an exposed area.

A part of the substrate 300 may penetrate the first conductive contact layer 310, the first conductive semiconductor layer 101, and the active layer 102 and may constitute a conductive via V connected with the second conductive semiconductor layer 103. A part of the substrate 300 may be the conductive via V, and the substrate 300 may include a conductive material.

The number of conductive vias V, the shape of the conductive via V, a pitch of the conductive via V, and a contact area with the second conductive semiconductor layer 103 may be suitably controlled so that contact resistance decreases. The conductive via V may be electrically separated from the first conductive contact layer 310, the first conductive semiconductor layer 101, and the active layer 102, and an insulator 120 may be positioned thereamong.

If the insulator 120 were just a material having an electrical insulating property, the insulator may be used without a limit. In an implementation, the insulator 120 may be a material minimally absorbing light, and may include silicon oxide or silicon nitride.

As described above, in the semiconductor light emitting device according to the exemplary embodiment of FIG. 9, the via V may be formed in the second conductive semiconductor layer 103 to apply voltage on the bottom of the second conductive semiconductor layer 103. For example, an electrode for applying voltage may not be formed on the top of the second conductive semiconductor layer 103 from which the light is extracted, and the light extraction efficiency may be enhanced.

In an implementation, as illustrated in FIG. 9, the voltage may be supplied to the second conductive semiconductor layer 103 through the conductive via V extended from the substrate 300.

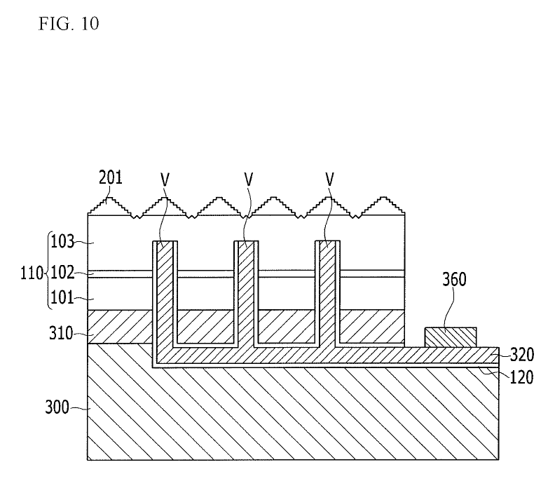

FIG. 10 illustrates a voltage application structure of a semiconductor light emitting device according to another exemplary embodiment. Referring to FIG. 10, the semiconductor light emitting device according to the exemplary embodiment may further include a second conductive contact layer 320 on the substrate 300. The conductive via V may extend from (e.g., as a part of) the second conductive contact layer 320, may penetrate the first conductive contact layer 310, the first conductive semiconductor layer 101, and the active layer 102, and may be connected with the second conductive semiconductor layer 103. The insulator 120 may be positioned between the conductive via V and the first conductive contact layer 310, the first conductive semiconductor layer 101, and the active layer 102, and the substrate 300.

A part of the second conductive contact layer 320 may be exposed and a second electrode pad 360 may be positioned on the exposed top. Therefore, the second conductive semiconductor layer 103 may receive voltage from the second electrode pad 360 and the first conductive semiconductor layer 101 may receive the voltage through the first conductive contact layer 310. In an implementation, the first conductive contact layer 310 may be omitted and the first conductive semiconductor layer 101 may directly receive the voltage from the conductive substrate 300.

In an implementation, as illustrated in FIGS. 9 and 10, the first electrode pad 350 or the second electrode pad 360 may at one edge of the light emitting structure 110. In an implementation, the first electrode pad 350 or the second electrode pad 360 may be positioned at the center of the light emitting structure 110. In this case, a via for forming the electrode pad may be positioned at the center of the light emitting structure 110.

In an implementation, as illustrated in FIGS. 9 and 10, a voltage application structure may be based on one light emitting structure 110. In an implementation, the semiconductor light emitting device may include a plurality of light emitting structures. In the exemplary embodiment, the second conductive semiconductor layer of one light emitting structure and the first conductive semiconductor layer of another light emitting structure adjacent thereto may be electrically connected with each other (n-p junction).

In an implementation, the second conductive semiconductor layer of one light emitting structure and the second conductive semiconductor layer of another light emitting structure adjacent thereto may be electrically connected with each other (n-n junction) and the first conductive semiconductor layer of one light emitting structure and the first conductive semiconductor layer of another light emitting structure adjacent thereto may be electrically connected with each other (p-p junction). In an implementation, three connection types may be mixed in one semiconductor light emitting device.

In an implementation, the first electrode pad 350 or the second electrode pad 360 may be adjacent to the light emitting structure. In an implementation, the first electrode pad 350 and the second electrode pad 360 may be positioned below the light emitting structure. For example, the first conductive semiconductor layer 101 and the second conductive semiconductor layer 103 may receive the voltage from the bottom of the substrate.

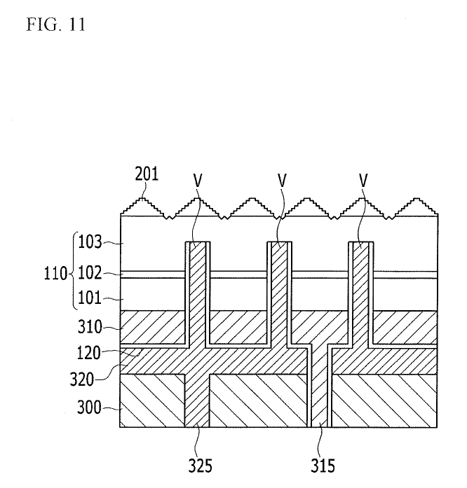

FIG. 11 illustrates a voltage application structure of a semiconductor light emitting device according to another exemplary embodiment. Referring to FIG. 11, the first conductive contact layer 310 and the second conductive contact layer 320 may be positioned between the light emitting structure 110 and the substrate 300. The first conductive contact layer 310 and the second conductive contact layer 320 may be insulated from each other through the insulator 120. The substrate 300 may be insulating.

The first conductive contact layer 310 may contact the first conductive semiconductor layer 101 and the first conductive contact layer 310 may include a first terminal 315 penetrating the substrate 300. In an implementation, the first terminal 315 may be connected with the first electrode pad to supply the voltage to the first conductive semiconductor layer 101.

The second conductive contact layer 320 may contact the second conductive semiconductor layer 103 through the conductive via V, and the second conductive contact layer 320 may include a second terminal 325 penetrating the substrate 300. In an implementation, the second terminal 325 may be connected with the second electrode pad to supply the voltage to the second conductive semiconductor layer 103.

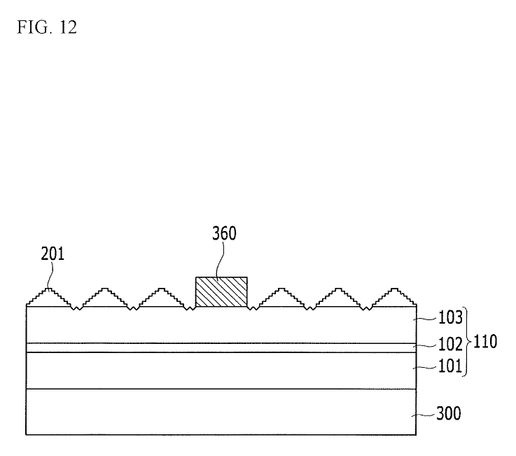

In an implementation, the second conductive semiconductor layer 103 may receive the voltage from the bottom by the conductive via V penetrating the inside of the second conductive semiconductor layer 103. In an implementation, the second electrode pad 360 may be positioned on the top of the second conductive semiconductor layer 103 to receive the voltage. FIG. 12 illustrates a voltage application structure of a semiconductor light emitting device according to another exemplary embodiment. Referring to FIG. 12, in the semiconductor light emitting device according to the exemplary embodiment, a part of the protrusion 201 may be removed, the second electrode pad 360 directly contacting the second conductive semiconductor layer 103 may be positioned, and as a result, the second conductive semiconductor layer 103 may receive the voltage from the second electrode pad 360.

Hereinabove, various voltage application structures of the semiconductor light emitting device according to the exemplary embodiment has been described. In an implementation, various voltage application structures that supply the voltage from the bottom of the light emitting structure 110 through the via V penetrating the first conductive semiconductor layer 101 or the second conductive semiconductor layer 103, or supplies the voltage through the second electrode pad 360 positioned on the top of the second conductive semiconductor layer 103 may be included.

Hereinafter, a method for manufacturing a semiconductor light emitting device according to an exemplary embodiment will be described with reference to drawings.

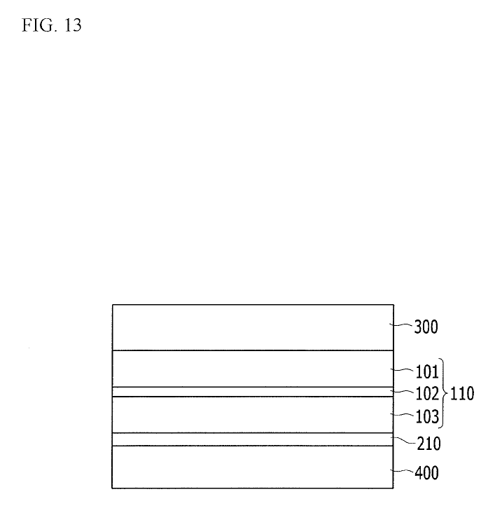

FIGS. 13 to 17 illustrate process diagrams schematically showing stages in a process of manufacturing a semiconductor light emitting device according to an exemplary embodiment.

First, referring to FIG. 13, an undoped semiconductor layer 210, a second conductive semiconductor layer 103, an active layer 102, a first conductive semiconductor layer 101, and a substrate 300 may be sequentially formed on a substrate 400 for semiconductor growth.

The substrate 400 for semiconductor growth may include, e.g., silicon, sapphire, SiC, MgAl₂O₄, MgO, LiAlO₂, LiGaO₂, or GaN. In order to grow the undoped semiconductor layer 210 including GaN on the substrate 400 for semiconductor growth, the substrate 400 for semiconductor growth may be a sapphire substrate or a spinel (MgAl₂O₄) substrate which has a similar lattice structure to that of a GaN-based semiconductor.

In an implementation, the undoped semiconductor layer 210 may include GaN. The undoped semiconductor layer 210 may be used as a buffer layer before growth of the semiconductor layer configuring a light emitting structure 110 and may help alleviate a lattice defect of the light emitting structure 110 grown thereon. In an implementation, the undoped semiconductor layer 210 may be formed with a thickness of about 1,000 angstroms.

In an implementation, the first conductive semiconductor layer 101 may be a p type semiconductor layer and the second conductive semiconductor layer 103 may be an n type semiconductor layer. The first conductive semiconductor layer 101 and the second conductive semiconductor layer 103 may include nitride semiconductors. In an implementation, the first conductive semiconductor layer 101 and the second conductive semiconductor layer 103 may have a composition equation of AlₓIn_{y}Ga_{(1-x-y)}N (herein, 0=x=1, 0=y=1, 0=x+y=1). In an implementation, the first conductive semiconductor layer 101 and the second conductive semiconductor layer 103 may include GaN, AlGaN or InGaN. In an implementation, the active layer 102 may have a multiple quantum well (MQW) structure in which quantum well layers and quantum barrier layers are alternately stacked and may have a InGaN/GaN structure.

The substrate 300 may support the light emitting structure 110 when the substrate 400 for semiconductor growth is removed in a subsequent step. The substrate 300 may include, e.g., Au, Ni, Al, Cu, W, Si, Se or GaAs. In an implementation, the substrate 300 may be conductive or non-conductive and may be formed in a process such as plating, sputtering, and deposition.

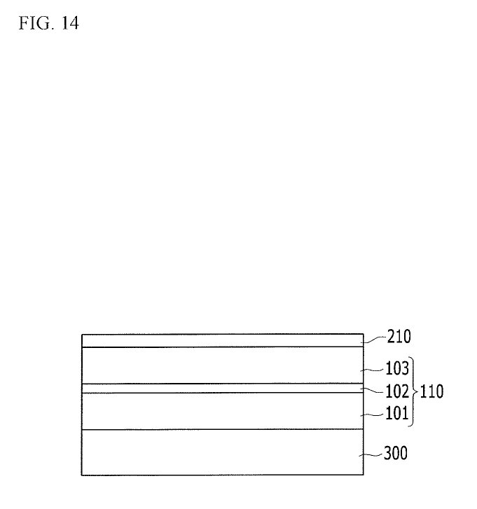

Next, referring to FIG. 14, the substrate 400 for semiconductor growth may be removed. The substrate 400 for semiconductor growth may be removed by a laser lift-off or chemical lift-off process. FIG. 14 illustrates a state where the substrate 400 for semiconductor growth is removed and the state is illustrated while rotating at 180° as compared with FIG. 13.

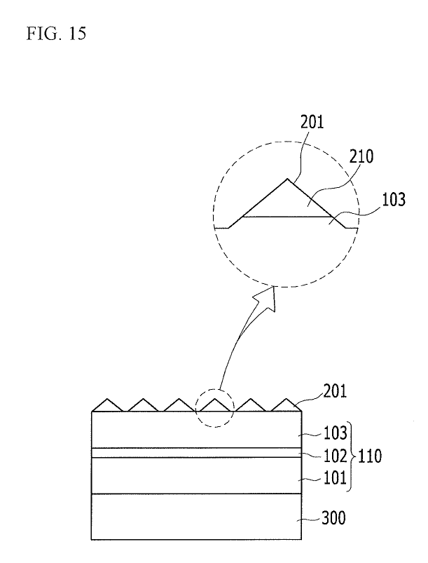

Next, referring to FIG. 15, a plurality of protrusions 201 including the undoped semiconductor layer 210 may be formed by dry-etching the undoped semiconductor layer 210. The plurality of protrusions 201 may be uniformly arranged. In the step, the second conductive semiconductor layer 103 between the protrusions 201 may be partially exposed by dry etching.

In this step, the dry etching may be performed by supplying gas including Cl₂ and BCl₃. In an implementation, the dry etching may be performed for 5 to 15 minutes while supplying gas including Cl₂ and BCl₃ at 100 to 300 SCCM. Maintaining the supply speed of the gas at 100 SCCM or greater may help ensure that the dry etching is sufficiently performed. Maintaining the supply speed of the gas at 300 SCCM or less may help prevent overetching from occurring. Maintaining the reaction time at 5 minutes or greater may help ensure that the dry etching is sufficiently performed. Maintaining the reaction time at 15 minutes or less may help prevent overetching from occurring.

In this step, gas of Cl₂ and BCl₃ and the undoped semiconductor layer 210 may chemically react with each other and then etching may be performed. In an implementation, the gas used in the step may include a suitable gas that chemically reacts with the undoped semiconductor layer 210 to be dry-etched.

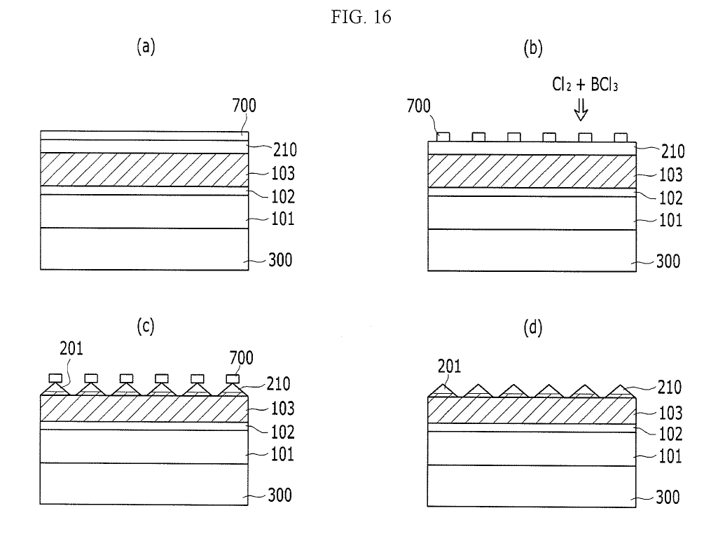

FIG. 16 illustrates the etching step in more detail. Referring to part (a) of FIG. 16, the photoresist 700 may be positioned on the undoped semiconductor layer 210. Next, as illustrated in part (b) of FIG. 16, the photoresist 700 may be patterned and the gas may be supplied by using the patterned photoresist 700 as a mask. In this case, the supplied gas may dry-etch the undoped semiconductor layer 210.

As a result, as illustrated in part (c) of FIG. 16, the undoped semiconductor layer may be etched to include the plurality of protrusions 201. Next, as illustrated in part (d) of FIG. 16, the plurality of protrusions 201 may be formed by removing the photoresist 700.

Each of the plurality of protrusions 201 formed in the dry-etching step may have a shape similar to a cone. In this specification, the shape similar to the cone may include all structures of which a bottom is a circle or nearly circular and a diameter of a cross section is decreased toward the top. Further, a generating line of the cone may be a curve having an arc.

In the step, the dry etching may be performed until the second conductive semiconductor layer 103 is exposed. For example, the second conductive semiconductor layer 103 may be exposed between the plurality of protrusions 201 including an undoped semiconductor layer 210 material.

The protrusion 201 may include only the undoped semiconductor layer 210 material. In an implementation, in the dry etching process, in the case of being etched up to the second conductive semiconductor layer 103, the plurality of protrusions 201 may have a two layer structure in which the second conductive semiconductor layer 103 material is positioned below the inside, and the undoped semiconductor layer 210 material is positioned above. FIGS. 15 and 16 illustrate a case where the protrusions 201 have a double structure. In an implementation, the protrusions may have a single layer structure including only the undoped semiconductor layer 210 material therein.

When the protrusions 201 have the double structure, after the dry etching of the step, the thickness of the second conductive semiconductor layer 103 may be somewhat decreased. For example, a part of the second conductive semiconductor layer 103 may be etched to be included in the protrusion 201.

An angle between the side and the bottom of the protrusion 201 formed in the step may be 30° to 60°. Maintaining the angle between the side and the bottom of the protrusion 201 at 60° or less may help ensure that the generated light is not trapped between the protrusions 201, thereby ensuring that light emitting efficiency is not deteriorated. Maintaining the angle between the side and the bottom of the protrusion 201 at 30° or greater may help ensure a sufficient improvement of the light emitting efficiency caused by forming the protrusions is exhibited.

The heights of the protrusions 201 may be between 1 and 2 μm. In an implementation, the bottom of each protrusion may be a circle and the diameter may be between 2.7 and 3.2 μm.

The bottom diameters of the protrusion 201 may coincide with each other (e.g., may be uniform) in the entire area of the second conductive semiconductor layer 103 or may be different from each other. In an implementation, diameters of bottoms of adjacent protrusions 201 may be different from each other and a difference thereof may be within 20%.

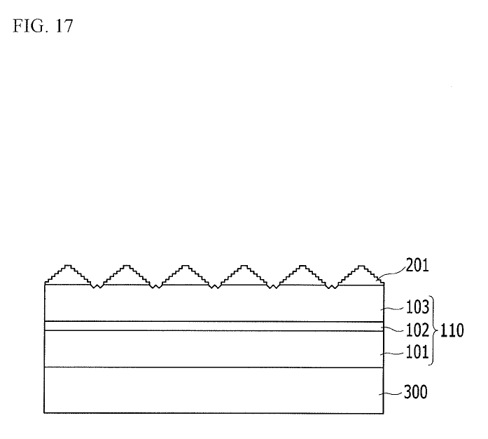

Next, referring to FIG. 17, an unevenness (which is smaller than a size of the protrusion) may be formed on the surface of the protrusion 201 and the surface of the exposed second conductive semiconductor layer 103 by supplying the gas to the protrusion 201 and the exposed second conductive semiconductor layer 103.

The step may be a step of forming an unevenness by texturing the surface of the protrusion 201 and the surface of the second conductive semiconductor layer 103 exposed between the protrusions.

The step may be performed for 30 sec to 3 min while supplying gas at 50 SCCM to 200 SCCM. Maintaining the supply speed of the gas at 50 SCCM or greater may help ensure that the surface texturing occurs well. Maintaining the supply speed at 200 SCCM or less helps ensure that the surface texturing does not excessively occur. Maintaining the supply time of the gas at 30 sec or greater may help ensure that the texturing sufficiently occurs. Maintaining the supply time at 3 min or less may help ensure that the shape of the protrusion is maintained and may help prevent excessive texturing.

In an implementation, the gas used in the step may be, e.g., a mixed gas of inert gas and cleaning gas. In an implementation, the gas used in the step may also include only the inert gas and may include a combination of the inert gas and other gases. The inert gas may have a predetermined energy and may collide with the surface between the protrusions 201 to form an unevenness. The cleaning gas may help remove impurities formed on the surface of the protrusion and the surface between the protrusions by collision of the inert gas. In an implementation, the inert gas may include, e.g., argon, neon, helium, nitrogen or carbon dioxide. In an implementation, the cleaning gas may include, e.g., oxygen, CF₃ or NF₃. In an implementation, the mixed gas may be mixed gas of argon and oxygen. In this case, the argon may collide with the surface of the protrusion 201 and the surface of the second conductive semiconductor layer 103 between the protrusions to form an unevenness having a size smaller than the size of the protrusion 201 and the oxygen removes the impurities formed on the surface.

In an implementation, the gas may include a suitable gas that collides with the protrusion 201 and the surface of the exposed second conductive semiconductor layer 103 and can form surface roughness on the surface.

In this step, the size of the unevenness formed on the exposed second conductive semiconductor layer 103 may be larger than the size of the unevenness formed on the surface of the protrusion 201. For example, the protrusion 201 may mostly include the undoped semiconductor layer 201 material, the second conductive semiconductor layer 103 may include a doped semiconductor layer material, and properties may be different from each other. In an implementation, the surface of the protrusion 201 may be a slope, the surface between the protrusions 201 may be a planar surface, and thus the collision degrees of the gas of the surface of the protrusion 201 and the surface between the protrusions 201 may be different from each other. For example, the gas may collide with the surface between the protrusions 201 which is the planar surface with high energy, and as a result, the unevenness may be formed to be large, but the gas may not collide with the surface of the protrusion 201 (which is the slope) with sufficient energy, and as a result, the unevenness may be formed to be small.

A ratio of an average size of the unevenness on the surface of the protrusion 201 and an average size of the unevenness between the protrusions 201 may be between 1:1 and 1:3. For example, the average size of the unevenness positioned between the protrusions 201 may be about 30% larger than the average size of the unevenness positioned on the surface of the protrusion 201.

In an implementation, the unevenness may cover the entire surface of the protrusion 201 or the unevenness may be formed only in a partial area of the surface of the protrusion 201. In an implementation, the unevenness positioned on the surface of the protrusion 201 may be formed to cover 70% to 100% of an area of the entire surface of the protrusion 201. In an implementation, the unevennesses may also be regularly positioned on the surface of the protrusion and irregularly positioned.

As such, when the plurality of protrusions is formed by dry-etching the updoped semiconductor layer positioned on the light emitting structure and the unevenness having the size smaller than the size of the protrusion is formed on the surface of the protrusion and the surface of the exposed second conductive semiconductor layer between the protrusions by using the gas, the light emitting efficiency of the semiconductor light emitting device may be improved.

Further, in the method of manufacturing the semiconductor light emitting device according to the exemplary embodiment, in the process of forming the complex unevenness structure, wet etching may not be used, and only the dry etching and surface texturing processes may be used. Accordingly, there may be no damage to the substrate and the light emitting structure by an etching solution used in wet etching and the plurality of protrusions may be uniformly formed. For example, in the case of using the wet etching, the protrusions or the unevennesses on the surface of the protrusion may be ununiformly formed. In an implementation, the plurality of protrusions may be uniformly formed by using dry etching.

In the exemplary embodiment above, the manufacturing process is briefly described based on the processes of forming the protrusions of the semiconductor light emitting device and forming the unevenness on the surface. In an implementation, the method of manufacturing the semiconductor light emitting device according to the exemplary embodiment of the present invention may further include a process of forming a conductive via for applying voltage.

For example, a process of forming a conductive via may be further included between the process of forming sequentially the undoped semiconductor layer, the second conductive semiconductor layer, the active layer, and the first conductive semiconductor layer on the substrate for semiconductor growth and the process of removing the substrate for semiconductor growth. Hereinafter, the process of forming the conductive via will be described.

FIG. 16 schematically illustrates the process of forming the conductive via.

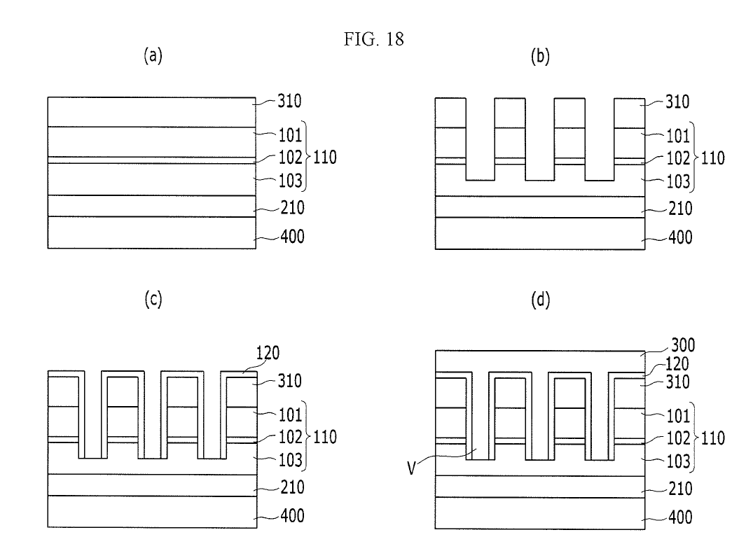

Referring to part (a) of FIG. 18, the light emitting structures 110 including the undoped semiconductor layer 210, the second conductive semiconductor layer 103, the active layer 102, and the first conductive semiconductor layer 101 may be sequentially stacked on the substrate 400 for semiconductor growth and a first conductive contact layer 310 may be formed.

Next, referring to part (b) of FIG. 18, vias may be formed in the first conductive contact layer 310 and the light emitting structure 110. The vias may pass through the first conductive contact layer 310, the first conductive semiconductor layer 101, and the active layer 102 to extend up to a partial area of the second conductive semiconductor layer 103.

Next, referring to part (c) of FIG. 18, an insulator 120 may be formed to cover the top of the first conductive contact layer 310 and the side wall of the vias. For example, the insulator 120 may not cover the lower surface of the vias.

Next, as illustrated in part (d) of FIG. 18, a conductive material may be formed inside the vias and on the insulating layer to form a conductive substrate 300 and a conductive vias V. Accordingly, the conductive substrate may be a structure connected with the conductive via connected with the second conductive semiconductor layer 103.

Next, the removing of the substrate 400 for semiconductor growth and the etching of the undoped semiconductor layer may be performed through the processes of FIGS. 14 to 17 as described above.

As is traditional in the field of the instant application, embodiments are described, and illustrated in the drawings, in terms of functional blocks, units, and/or modules. Those skilled in the art will appreciate that these blocks, units, and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or similar, they may be programmed using software (e.g., microcode) to perform various functions discussed herein and may optionally be driven by firmware and/or software. Alternatively, each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of the embodiments may be physically separated into two or more interacting and discrete blocks, units, and/or modules without departing from the scope of the instant application. Further, the blocks, units, and/or modules of the embodiments may be physically combined into more complex blocks, units, and/or modules without departing from the scope of the instant application.

The process of forming the conductive via is exemplified and the semiconductor light emitting device may be formed by various methods according to a voltage applying structure of the manufactured semiconductor light emitting device.

By way of summation and review, in the semiconductor light emitting device, light emitting efficiency can be expressed by multiplying internal quantum efficiency and light extraction efficiency. In this case, the internal quantum efficiency may be determined according to the quality of a semiconductor used, a structure of the light emitting device, and/or current injection efficiency, and the light extraction efficiency may be determined by a ratio of the generated light to be emitted to the outside of a semiconductor layer. Therefore, even though devices having the same internal quantum efficiency may be manufactured, the light emitting efficiency may vary depending on the light extraction efficiency.

At an interface of material layers having different refractive indexes, e.g., between the semiconductor layer and air, progress of light depending on the refractive index of each material layer may be limited. In the case of a flat interface, when the light is radiated from the semiconductor layer having a large refractive index (n>1) to an air layer having a small refractive index (n=1), the light may need to be incident in the flat interface having an angle less than a predetermined angle (a threshold angle) based on a vertical direction of the interface. When the light is incident at an angle at which full reflection is achieved, or more, the full reflection occurs on the flat interface, and as a result, the light extraction efficiency could significantly decrease. The embodiments may provide various methods for minimizing the significant decrease of the light extraction efficiency.

The embodiments may provide a semiconductor light emitting device having improved light extraction efficiency.

According to exemplary embodiments of the present invention, light extraction efficiency can be enhanced through an uneven complex structure and the uneven complex structure can be formed without damage to a light emitting structure.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

### DESCRIPTION OF SYMBOLS

| | |
|---|---|
| 101: First conductive semiconductor | 102: Active layer |
| layer | |
| 103: Second conductive semiconductor | 110: Light emitting structure |
| layer | |
| 201: Protrusion | 120: Insulator |
| 210: Undoped semiconductor layer | 300: Substrate |
| 350: First electrode pad | 360: Second electrode pad |
| 400: Semiconductor growth substrate | |

What is claimed is:

1. A semiconductor light emitting device, comprising:
a substrate;
a first conductive semiconductor layer on one surface of the substrate;
an active layer on the first conductive semiconductor layer;
a second conductive semiconductor layer on the active layer; and
a plurality of protrusions on the second conductive semiconductor layer, the plurality of protrusions including an undoped semiconductor material,
wherein an uneven complex surface structure including an unevenness that is a smaller size than a protrusion is formed in the second conductive semiconductor layer and is provided between the plurality of protrusions.

2. The semiconductor light emitting device as claimed in claim 1, wherein:
the protrusions each have a two layer structure, and
a lower layer of each protrusion further includes a material of the second conductive semiconductor layer.

3. The semiconductor light emitting device as claimed in claim 1, wherein an angle formed by a side and a bottom of each protrusions is 30° to 60°.

4. The semiconductor light emitting device as claimed in claim 1, wherein:
a diameter of a bottom of each protrusion is 2.7 μm to 3.2 μm, and
the diameter of the bottom of one protrusion of the plurality of protrusions is different from the diameter of another protrusion of the plurality of protrusions that is adjacent to the one protrusion.

5. The semiconductor light emitting device as claimed in claim 1, wherein a surface of each protrusion has an unevenness.

6. The semiconductor light emitting device as claimed in claim 5, wherein the unevenness of the surface of each protrusion covers an area of 70 to 100% of an entire surface of the protrusion.

7. The semiconductor light emitting device as claimed in claim 5, wherein a ratio of an average size of the unevenness on the surface of each protrusion and the average size of the unevenness between the protrusions is 1:1 to 1:3.

8. The semiconductor light emitting device as claimed in claim 1, wherein:
the plurality of protrusions are regularly positioned,
a cross section parallel to the substrate of each protrusion is circular,
a diameter of the cross section decreases in an upward direction of the protrusion, and
the undoped semiconductor material is GaN which is not intentionally doped.

9. The semiconductor light emitting device as claimed in claim 1, further comprising a conductive via connected with the second conductive semiconductor layer and penetrating the first conductive semiconductor layer and the active layer,
wherein:
the conductive via is insulated from the first conductive semiconductor layer and the active layer, and
the conductive via is electrically connected with a pad supplying voltage to the second conductive semiconductor layer.

10. A method of manufacturing a semiconductor light emitting device, the method comprising:
sequentially forming an undoped semiconductor layer, a second conductive semiconductor layer, an active layer, and a first conductive semiconductor layer on a semiconductor growth substrate;
removing the semiconductor growth substrate;
dry-etching the undoped semiconductor layer to form a plurality of protrusions from the undoped semiconductor layer and to partially expose the second conductive semiconductor layer; and
forming an unevenness having a smaller size than the protrusions by supplying gas to the protrusions and the exposed second conductive semiconductor layer, the unevenness being on a surface of the protrusions and a surface of the exposed second conductive semiconductor layer.

11. The method as claimed in claim 10, wherein:
the gas is mixed gas of an inert gas and a cleaning gas,
the inert gas includes argon, neon, helium, nitrogen, or carbon dioxide, and
the cleaning gas includes oxygen, CF₃, or NF₃.

12. The method as claimed in claim 10, wherein forming the unevenness having the smaller size than the protrusions on the surface of the protrusions and the surface of the exposed second conductive semiconductor layer is performed for 30 seconds to 3 minutes while supplying the gas at 50 SCCM to 200 SCCM.

13. The method as claimed in claim 10, wherein:
the protrusions each have a two layer structure, and
a lower layer of each protrusion includes a material of the second conductive semiconductor layer.

14. The method as claimed in claim 10, wherein:
the plurality of protrusions are regularly arranged,
a cross section parallel to the substrate of each protrusion is circular, and
a diameter of the cross section decreases in an upward direction of the protrusion.

15. The method as claimed in claim 10, further comprising, between the sequentially forming of the undoped semiconductor layer, the second conductive semiconductor layer, the active layer, and the first conductive semiconductor layer on the semiconductor growth substrate, and the removing of the semiconductor growth substrate:
forming a via that penetrates the first conductive semiconductor layer and the active layer and that extends up to a part of the second conductive semiconductor layer;
forming an insulator that covers a top of the first conductive semiconductor layer and a side wall of the via; and
forming a conductive material in the via and on the insulator.

16. A semiconductor light emitting device, comprising:
a first conductive semiconductor layer;
an active layer on the first conductive semiconductor layer;
a second conductive semiconductor layer on the active layer; and
a plurality of protrusions on the second conductive semiconductor layer, the plurality of protrusions including an undoped semiconductor material, the undoped semiconductor material being different from a material of the second conductive semiconductor layer,
wherein a surface of the second conductive semiconductor layer between the protrusions has an uneven complex surface structure including an unevenness.

17. The semiconductor light emitting device as claimed in claim 16, wherein the unevenness of the uneven complex structure has a pattern of peaks and valleys, a height of peaks being a smaller size than a height of the protrusions of the plurality of protrusions.

18. The semiconductor light emitting device as claimed in claim 16, wherein a surface of each protrusion has an uneven complex surface structure including an unevenness.

19. The semiconductor light emitting device as claimed in claim 16, wherein the protrusions each have a two-layer structure, the two-layer structure including a same material as the second conductive semiconductor layer as a base adjacent to the second conductive semiconductor layer and including the undoped semiconductor material on the base.

20. A semiconductor light emitting device prepared according to the method as claimed in claim 10.
